(19) United States
(12) Patent Application Publication
(10) Pub. No.: US 2025/0287572 A1
(43) Pub. Date: Sep. 11, 2025

(54) SEMICONDUCTOR DEVICE INCLUDING ACTIVE PATTERN AND CONDUCTIVE PAD PATTERN

(71) Applicant: Samsung Electronics Co., Ltd., Suwon-si (KR)

(72) Inventors: Jihoon Chang, Suwon-si (KR); Jaejoon Song, Suwon-si (KR)

(21) Appl. No.: 18/816,236

(22) Filed: Aug. 27, 2024

(30) Foreign Application Priority Data
Mar. 6, 2024 (KR) 10-2024-0032012

(51) Int. Cl. H10B 12/00

(52) U.S. Cl. CPC H10B 12/482; H10B 12/315; H10B 12/488

(57) ABSTRACT

A semiconductor device includes a bit line, an active pattern on the bit line, and including a lower active portion electrically connected to the bit line, a first vertical active portion extending upwardly from the lower active portion, and a second vertical active portion extending upwardly from the lower active portion, a word line between a lower region of the first vertical active portion and a lower region of the second vertical active portion, and a conductive pad pattern electrically connected to an upper region of the first vertical active portion and an upper region of the second vertical active portion.

### CROSS-REFERENCE TO RELATED APPLICATION(S)

This application claims the benefit under 35 USC 119(a) of Korean Patent Application No. 10-2024-0032012 filed on Mar. 6, 2024 in the Korean Intellectual Property Office, the entire disclosure of which is incorporated herein by reference for all purposes.

### BACKGROUND

The present inventive concept relates to a semiconductor device including an active pattern and a conductive pad pattern electrically connected and a method of forming the same.

Research is underway to reduce the size and improve the performance of elements in semiconductor devices. For example, in DRAMs, research is underway to reliably and stably form elements having a reduced size, but as the size of the elements is reduced, dispersion characteristics of semiconductor devices are deteriorating.

### SUMMARY

Example embodiments provide a semiconductor device in which integration may be increased and performance may be improved.

Example embodiments provide a method of forming the semiconductor device.

According to example embodiments, a semiconductor device is provided. The semiconductor device includes a bit line, an active pattern on the bit line, and including a lower active portion electrically connected to the bit line, a first vertical active portion extending from the lower active portion, and a second vertical active portion extending from the lower active portion, with the first vertical active portion and the second vertical active portion are spaced apart from one another, a word line between a lower region of the first vertical active portion and a lower region of the second vertical active portion, and a conductive pad pattern electrically connected to an upper region of the first vertical active portion and an upper region of the second vertical active portion.

According to example embodiments, a semiconductor device is provided. The semiconductor device includes a conductive line extending in a first horizontal direction, a first active pattern and a second active pattern on the conductive line, a first gate electrode and a second gate electrode on a level higher than a level of the conductive, and a first conductive pad pattern and a second conductive pad pattern on the first and second gate electrodes, respectively. Each of the first and second active patterns includes a lower active portion electrically connected to an upper surface of the conductive line, a first vertical active portion extending from the lower active portion, and a second vertical active portion extending from the lower active portion. The first gate electrode is between the first vertical active portion of the first active pattern and the second vertical active portion of the first active pattern, and is on the lower active portion of the first active pattern. The second gate electrode is between the first vertical active portion of the second active pattern and the second vertical active portion of the second active pattern, and is on the lower active portion of the first active pattern. The first conductive pad pattern is electrically connected to the first vertical active portion of the first active pattern and the second vertical active portion of the first active pattern. The second conductive pad pattern is electrically connected to the first vertical active portion of the second active pattern and the second vertical active portion of the second active pattern.

According to example embodiments, a semiconductor device is provided. A semiconductor device includes a conductive line extending in a first horizontal direction, a cell transistor on the conductive line, and a conductive pad pattern on the cell transistor. The cell transistor includes an active pattern including a first vertical channel portion and a second vertical channel portion spaced apart from each other in the first horizontal direction, a single gate electrode between the first and second vertical channel portions, and a gate dielectric layer between the single gate electrode and the active pattern. The conductive pad pattern contacts upper regions of the first and second vertical channel portions.

### BRIEF DESCRIPTION OF DRAWINGS

The above and other aspects, features, and advantages of the present inventive concept will be more clearly understood from the following detailed description, taken in conjunction with the accompanying drawings, in which:

FIGS. 1, 2A, and 2B are diagrams illustrating a semiconductor device according to example embodiments;

FIG. 3 is a cross-sectional view illustrating a modified example of a semiconductor device according to example embodiments;

FIG. 4 is a cross-sectional view illustrating a modified example of a semiconductor device according to example embodiments;

FIG. 5 is a diagram illustrating a modified example of a semiconductor device according to example embodiments;

FIGS. 6, 7A, and 7B are diagrams illustrating modified examples of a semiconductor device according to example embodiments;

FIG. 8 is a cross-sectional view illustrating a modified example of a semiconductor device according to example embodiments;

FIG. 9 is a cross-sectional view illustrating a modified example of a semiconductor device according to example embodiments;

FIG. 10 is a cross-sectional view illustrating a modified example of a semiconductor device according to example embodiments;

FIGS. 11A, 11B, 12, 13A, 13B, 14A, and 14B are cross-sectional views illustrating an example of a method of forming a semiconductor device according to example embodiments; and

FIGS. 15A, 15B, 16A, 16B, 17A, 17B, 18A, and 18B are cross-sectional views illustrating another example of a method of forming a semiconductor device according to example embodiments.

### DETAILED DESCRIPTION

Hereinafter, terms such as “upper,” “intermediate,” “middle,” “lower” and the like may be replaced with other terms, such as “first,” “second,” “third” and the like to describe the elements of the specification. Terms such as “first,” “second” and “third” may be used to describe various elements, but the elements are not limited by the terms, and a “first element” may be referred to as a “second element.” In the specification, terms such as ‘lower’, ‘upper’, ‘upper end’, and ‘lower end’ may be terms that are described based on the drawings.

In the drawings, reference numerals displayed in formats such as “30(30_1)”, “30(30_2)”, and the like may mean that the element of reference numeral 30 may be plural, and a plurality of elements represented by reference numeral 30 may include a first element represented by symbol 30_1 and a second element represented by symbol 30_2.

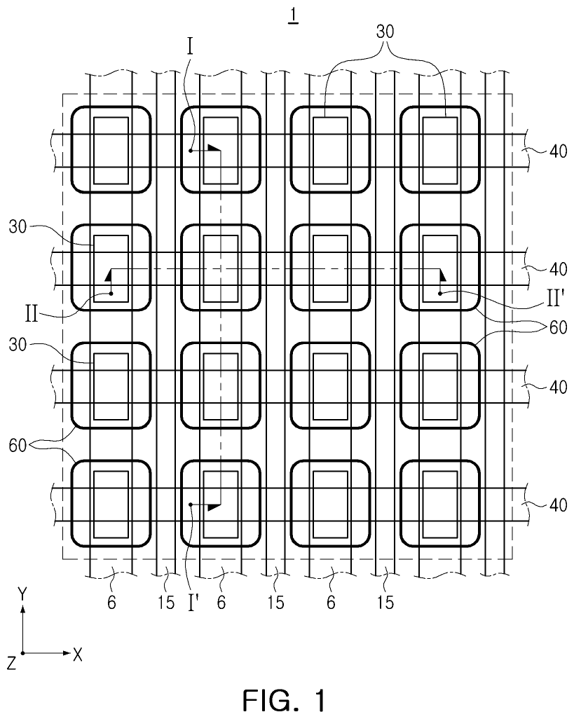

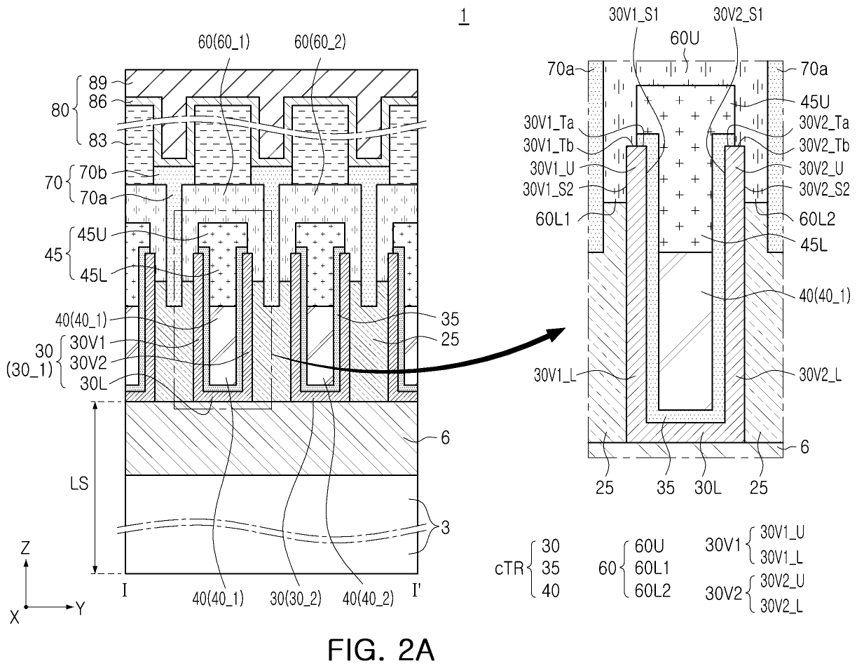

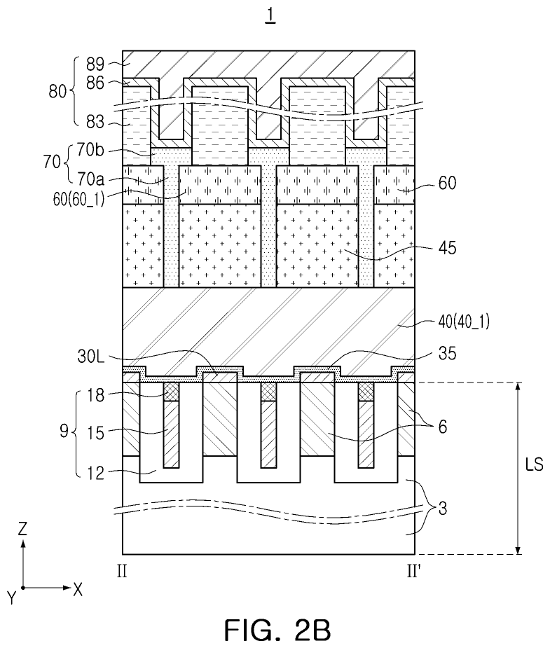

First, an illustrative example of a semiconductor device according to example embodiments will be described with reference to FIGS. 1, 2A, and 2B. In FIGS. 1 to 2B, FIG. 1 is a plan view illustrating a semiconductor device according to example embodiments, FIG. 2A is a cross-sectional view conceptually illustrating the area taken along line I-I′ of FIG. 1, and FIG. 2B is a partial enlarged view of the area indicated by II-II′ in FIG. 1.

Referring to FIGS. 1, 2A, and 2B, the semiconductor device 1 according to example embodiments may include a lower structure LS.

The lower structure LS may include a base 3 and conductive lines 6 on the base. The base 3 may include core circuits and peripheral circuits in memory such as DRAM. Each of the conductive lines 6 may have a line shape extending in the first horizontal direction Y. The conductive lines 6 may be spaced apart from each other in a second horizontal direction X perpendicular to the first horizontal direction Y. Each of the conductive lines 6 may include at least one conductive material layer. For example, each of the conductive lines 6 may include doped polysilicon, metal, conductive metal nitride, metal-semiconductor compound, conductive metal oxide, conductive graphene, carbon nanotube, or combinations thereof. For example, each of the conductive lines 6 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, graphene, carbon nanotube, or combinations thereof, but is not limited thereto. Each of the conductive lines 6 may comprise a single layer or multiple layers of the materials described above.

The conductive lines 6 may be bit lines 6 in a memory such as DRAM. Hereinafter, the conductive lines 6 will be described and referred to as ‘bit lines.’

The lower structure LS may further include shield structures 9 disposed between the bit lines 6. One of the shield structures 9 may be disposed between a pair of adjacent bit lines among the bit lines 6. Each of the shield structures 9 may include a shield conductive line 15, a shield insulating capping pattern 18 on the shield conductive line 15, and a shield insulating layer 12 covering, overlapping, or on the side surfaces of the shield conductive line 15 and the shield insulating capping pattern 18 and covering, overlapping, or on the lower surface of the shield conductive line 15, stacked sequentially. The shield conductive lines 15 may have a lower surface disposed at a lower level than level of the lower surface of the bit lines 6, and an upper surface disposed at a higher level than level of the lower surface of the bit lines 6 and a lower level than level of the upper surface of the bit lines 6. The shield conductive line 15 may screen capacitive coupling between the bit lines 6. For example, the shield conductive line 15 may significantly reduce the Resistive-Capacitive delay (RC delay) of the bit lines 6 by reducing or blocking parasitic capacitance between the bit lines 6. The shield conductive line 15 is formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaiN, RuTiN, NiSi, CoSi, IrOx, RuOx, graphene, carbon nanotubes, or combinations thereof, but is not limited thereto. The shield conductive line 15 may include a single layer or multiple layers of the materials described above.

The semiconductor device 1 may further include insulating patterns 25 disposed on the lower structure LS. Each of the insulating patterns 25 may have a line shape extending in the second horizontal direction X. The insulating patterns 25 may be formed of an insulating material such as silicon oxide.

The semiconductor device 1 may further include active patterns 30 arranged in the first horizontal direction Y and the second horizontal direction X. The active patterns 30 may be semiconductor patterns or channel patterns. The active patterns 30 may include a semiconductor material. For example, the active patterns 30 may include an oxide semiconductor. The oxide semiconductor may be indium gallium zinc oxide (IGZO). However, the example embodiments are not limited thereto. For example, the oxide semiconductor layer may include at least one of Indium Tungsten Oxide (IWO), Indium Tin Gallium Oxide (ITGO), Indium Aluminum Zinc Oxide (IAGO), Indium Gallium Oxide (IGO), Indium Tin Zinc Oxide (ITZO), zinc tin oxide (ZTO), indium zinc oxide (IZO), ZnO, Iindium gallium silicon oxide (GSO), indium oxide (InO), tin oxide (SnO), titanium oxide (TiO), zinc oxynitride (ZnON), magnesium zinc oxide (MgZnO), indium zinc oxide (InZnO)), indium gallium zinc oxide (InGaZnO), zirconium indium zinc oxide (ZrInZnO), hafnium indium zinc oxide (HfInZnO), tin indium zinc oxide (SnInZnO), aluminum tin indium zinc oxide (AlSnInZnO), silicon indium zinc oxide (SiInZnO), zinc tin oxide (ZnSnO), aluminum zinc tin oxide (AlZnSnO), gallium zinc tin oxide (GaZnSnO), zirconium zinc tin oxide (ZrZnSnO), and/or Indium Gallium Silicon Oxide (InGaSiO). The active patterns 30 may include the oxide semiconductor, but the example embodiments are not limited thereto. For example, the active patterns 30 may include a semiconductor material such as single crystal silicon or polysilicon.

The active patterns 30 may include a first active pattern 30_1 and a second active pattern 30_2 adjacent to each other in the first horizontal direction Y. Each of the active patterns 30 may include a lower active portion 30L disposed on the bit line 6 and connected to the bit line 6, a first vertical active portion 30V1 extending upwardly from the first side of the lower active portion 30L, and a second vertical active portion 30V2 extending upwardly from the second side of the lower active portion 30L.

In each of the active patterns 30, the lower active portion 30L may contact the upper surface of the bit line 6. In each of the active patterns 30, the lower surface of the lower active portion 30L may contact the upper surface of the bit line 6. In each of the active patterns 30, the first vertical active portion 30V1 and the second vertical active portion 30V2 may be arranged in the first horizontal direction Y. In each of the active patterns 30, the first vertical active portion 30V1 and the second vertical active portion 30V2 may be spaced apart from each other in the first horizontal direction Y. In each of the active patterns 30, the first vertical active portion 30V1 may include a first lower region 30V1_L and a first upper region 30V1_U on the first lower region 30V1_L, and the second vertical active portion 30V2 may include a first lower region 30V2_L and a first upper region 30V2_U on the first lower region 30V2_L. Upper surfaces of the first and second vertical active portions 30V1 and 30V2 may be disposed at a higher level than level of the upper surfaces of the insulating patterns 25. The first and second vertical active portions 30V1 and 30V2 may also be referred to as vertical channel portions or vertical channel layers.

The semiconductor device 1 may further include gate electrodes 40. The gate electrodes 40 may be word lines in memory such as DRAM. Hereinafter, the gate electrodes 40 will be described and referred to as ‘word lines.’

The word lines 40 may be disposed at a lower level than level of the upper surfaces of the first and second vertical active portions 30V1 and 30V2. The word lines 40 may be placed at a lower level than level of the upper surfaces of the insulating patterns 25. Each of the word lines 40 may have a line shape extending in the second horizontal direction X. The word lines 40 may be spaced apart from each other in the first horizontal direction Y. The word lines 40 may include a first word line 40_1 and a second word line 40_2 that are adjacent to each other in the first horizontal direction Y. The word lines 40 may be disposed on the lower active portions 30L and between the first vertical active portions 30V1 and the second vertical active portions 30V2. One of the word lines 40 may be disposed on one of the active patterns 30. For example, the first word line 40_1 may be disposed on the lower active portion 30L of the first active pattern 30_1, and may be disposed between the first vertical active portion 30V1 of the first active pattern 30_1 and the second vertical active portion 30V2 of the first active pattern 30 1. The first word line 40_1 may be disposed between the lower region 30V1_L of the first vertical active portion 30V1 and the lower region 30V2_L of the second vertical active portion 30V2 of the first active pattern 30_1. Each of the word lines 40 may include at least one conductive material. For example, each of the word lines 40 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, or combinations thereof, but is not limited thereto. Each of the word lines 40 may include a single layer or multiple layers of the materials described above.

The semiconductor device 1 may further include insulating capping patterns 45 on the word lines 40. The insulating capping patterns 45 may be formed of an insulating material such as silicon nitride or silicon oxynitride. Each of the insulating capping patterns 45 may include an upper capping portion 45U disposed at a higher level than level of the active pattern 30, and a lower capping portion 45L extending downwardly (i.e., towards the base 3) from the center of the upper capping portion 45U and contacting the upper surface of the word line 40. The upper capping portion 45U may include at least one vertically overlapping portion of the first and second vertical active portions 30V1 and 30V2.

The semiconductor device 1 may further include gate dielectric layers 35 disposed between the active patterns 30 and the word lines 40 and between the active patterns 30 and the insulating capping patterns 45. The gate dielectric layers 35 may be in contact with the active patterns 30 and the word lines 40, between the active patterns 30 and the word lines 40, and may be in contact with the active patterns 30 and the insulating capping patterns 45, between the active patterns 30 and the insulating capping patterns 45. For example, the gate dielectric layer 35 disposed between the first active pattern 30_1 and the first word line 40_1 may contact the first active pattern 30_1 and the first word line 40_1.

The semiconductor device 1 may further include conductive pad patterns 60 that vertically overlap the active patterns 30 and are connected to the active patterns 30.

Each of the conductive pad patterns 60 may include at least one conductive material layer. For example, each of the conductive pad patterns 60 may include doped silicon, metal, conductive metal nitride, metal-semiconductor compound, conductive metal oxide, conductive graphene, carbon nanotube, or combinations thereof. For example, each of the conductive pad patterns 60 may be doped silicon, Al, Cu, Ti, Ta, Ru, W, Mo, Pt, Ni, Co, TiN, TaN, WN, NON, TiAl, TiAlN, TiSi, TiSiN, TaSi, TaSiN, RuTiN, NiSi, CoSi, or combinations thereof, but is not limited thereto. Each of the conductive pad patterns 60 may include a single layer or multiple layers of the above-described materials.

The conductive pad patterns 60 may be placed at a higher level than level of the word lines 40. Each of the conductive pad patterns 60 may be connected to the upper region 30V1_U of the first vertical active portion 30V1 and the upper region 30V2_U of the second vertical active portion 30V2. Each of the conductive pad patterns 60 may include an upper pad portion 60U, a first lower pad portion 60L1 extending downwardly from the first side of the upper pad portion 60U and connected to the upper region 30V1_U of the first vertical active portion 30V1, and a second lower pad portion 60L2 extending downwardly from the second side of the upper pad portion 60U and connected to the upper region 30V2_U of the second vertical active portion 30V2. The width of each of the conductive pad patterns 60 in the first horizontal direction Y may be larger than the width of each of the word lines 40 in the first horizontal direction Y.

The conductive pad patterns 60 may include a first conductive pad pattern 60_1 and a second conductive pad pattern 60_2 adjacent to each other in the first horizontal direction Y. The first conductive pad pattern 60_1 may be connected to the upper regions 30V1_U and 30V2_U of the first and second vertical active portions 30V1 and 30V2 of the first active pattern 30_1. The second conductive pad pattern 60_2 may be connected to the upper regions 30V1_U and 30V2_U of the first and second vertical active portions 30V1 and 30V2 of the second active pattern 30_2.

In each of the active patterns 30, the first vertical active portion 30V1 may have a first side surface 30V1_S1 facing the second vertical active portion 30V2 and a second side surface 30V1_S2 facing the first side surface 30V1_S1, and the second vertical active portion 30V2 may have a third side surface 30V2_S1 facing the first vertical active portion 30V1 and a fourth side surface 30V2_S2 facing the third side surface 30V2_S1.

In each of the conductive pad patterns 60, the first lower pad portion 60L1 may contact the second side surface 30V1_S2 of the first vertical active portion 30V1, and the second lower pad portion 60L2 may contact the fourth side surface 30V2_S2 of the second vertical active portion 30V2. For example, the first lower pad portion 60L1 of the first conductive pad pattern 60_1 may be in contact with the second side surface 30V1_S2 of the first vertical active portion 30V1 of the first active pattern 30_1, and the second lower pad portion 60L2 of the first conductive pad pattern 60_1 may contact the fourth side surface 30V2_S2 of the second vertical active portion 30V2 of the first active pattern 30_1.

Each of the conductive pad patterns 60 may contact at least a portion of upper surfaces of the first and second vertical active portions 30V1 and 30V2. In the first active pattern 30_1 and the first conductive pad pattern 60_1 connected to each other, a least a portion of the upper surface (30V1_Ta, 30V1_Tb) of the first vertical active portion 30V1 may be in contact with the first lower pad portion 60L1, and a least a portion of the upper surfaces 30V2_Ta and 30V2_Tb of the second vertical active portion 30V2 may contact the second lower pad portion 60L2. For example, in the first active pattern 30_1 and the first conductive pad pattern 60_1 connected to each other, the upper surface (30V1_Ta, 30V1_Tb) of the first vertical active portion 30V1 may include a first surface 30V1_Ta in contact with the gate dielectric layer 35 without contacting the first lower pad portion 60L1, and a second surface 30V1_Tb in contact with the first lower pad portion 60L1. The upper surface (30V2_Ta, 30V2_Tb) of the second vertical active portion 30V2 may include a third surface 30V2_Ta in contact with the gate dielectric layer 35 without contacting the second lower pad portion 60L2, and a fourth surface 30V2_Tb in contact with the second lower pad portion 60L2.

The first lower pad portion 60L1 may be in contact with the second side surface 30V1_S2 of the first vertical active portion 30V1 and the second surface 30V1_Tb of the upper surface (30V1_Ta, 30V1_Tb) of the first vertical active portion 30V1. The second lower pad portion 60L2 may be in contact with the fourth side surface 30V2_S2 of the second vertical active portion 30V2 and the fourth surface 30V2_Tb of the upper surface (30V2_Ta, 30V2_Tb) of the second vertical active portion 30V2.

The upper capping portion 45U may overlap the first surface 30V1_Ta of the upper surfaces 30V1_Ta and 30V1_Tb of the first vertical active portion 30V1 in the vertical direction Z, and may overlap the third surface 30V2_Ta of the upper surface 30V2_Ta, 30V2_Tb of the second vertical active portion 30V2 in the vertical direction Z.

The semiconductor device 1 may further include an insulating structure 70 disposed between the conductive pad patterns 60 and on upper surfaces of the conductive pad patterns 60. The insulating structure 70 may include an insulating separation portion 70a and an insulating capping portion 70b. The insulating separation portion 70a is disposed between the conductive pad patterns 60 arranged in the first horizontal direction Y and extends into the insulating patterns 25, and may be disposed between the conductive pad patterns 60 arranged in the second horizontal direction X and between the insulating capping patterns 45. The insulating capping portion 70b is disposed at a higher level than level of the conductive pad patterns 60 and may be disposed on upper surfaces of the conductive pad patterns 60. The conductive pad patterns 60 may be spaced apart from each other by the insulating separation portion 70a. In the cross-sectional structure in the first horizontal direction Y as illustrated in FIG. 2A, the lower surface of the insulating separation portion 70a may contact the insulating patterns 25, and in the cross-sectional structure in the second horizontal direction X as illustrated in FIG. 2B, the lower surface of the insulating separation portion 70a may contact the word lines 40.

The semiconductor device 1 may further include an information storage structure 80. The information storage structure 80 may be a cell capacitor capable of storing information in a memory device such as DRAM. For example, the information storage structure 80 may include first electrodes 83 connected to the conductive pad patterns 60 while penetrating through the insulating capping portion 70b, and extending upwardly, a dielectric layer 86 disposed on the first electrodes 83 and the insulating capping portion 70b, and a second electrode 89 on the dielectric layer 86. The second electrode 89 may include a portion disposed between the first electrodes 83 and a portion disposed on upper surfaces of the first electrodes 83.

In example embodiments, the word lines 40, the active patterns 30, and the gate dielectric layers 35 may configure cell transistors cTR. The first and second vertical active portions 30V1 and 30V2 may be vertical channel regions of the cell transistors cTR. Therefore, the integration degree of the semiconductor device 1 may be increased.

In example embodiments, the first word line 40_1, the first active pattern 30_1, and the gate dielectric layer 35 between the first word line 40_1 and the first active pattern 30_1 may configure one cell transistor cTR.

Since the one cell transistor cTR may use the first and second vertical active portions 30V1 and 30V2 of the first active pattern 30_1 disposed on both sides of one first word line 40_1, for example, the first gate electrode 40_1, as vertical channel regions, Ion (ON-Current) of the one cell transistor cTR may be improved and channel resistance may be reduced. Accordingly, the performance of the semiconductor device 1 including the cell transistor cTR may be improved.

In example embodiments, the first and second vertical active portions 30V1 and 30V2 may be referred to as vertical channel portions or vertical channel regions.

The first conductive pad pattern 60_1 may contact upper regions 30V1_U and 30V2_U of the first and second vertical active portions 30V1 and 30V2 of the first active pattern 30_1, which may be vertical channel regions. Accordingly, contact resistance between the first conductive pad pattern 60_1 and the first active pattern 30_1 may be improved. Therefore, the performance of the semiconductor device 1 may be improved and reliability may be improved.

Hereinafter, various modifications to the above-described embodiment will be described to increase the degree of integration, improve performance, and improve reliability of the semiconductor device 1. Various examples of modifications to the elements of the semiconductor device 1 described below will be explained with a focus on modified elements or replaced elements. In addition, the modified or replaceable elements described below are described with reference to each drawing, but the modified and replaceable elements may be combined with each other, or may be combined with other elements described above, thereby forming the semiconductor device 1 according to example embodiments.

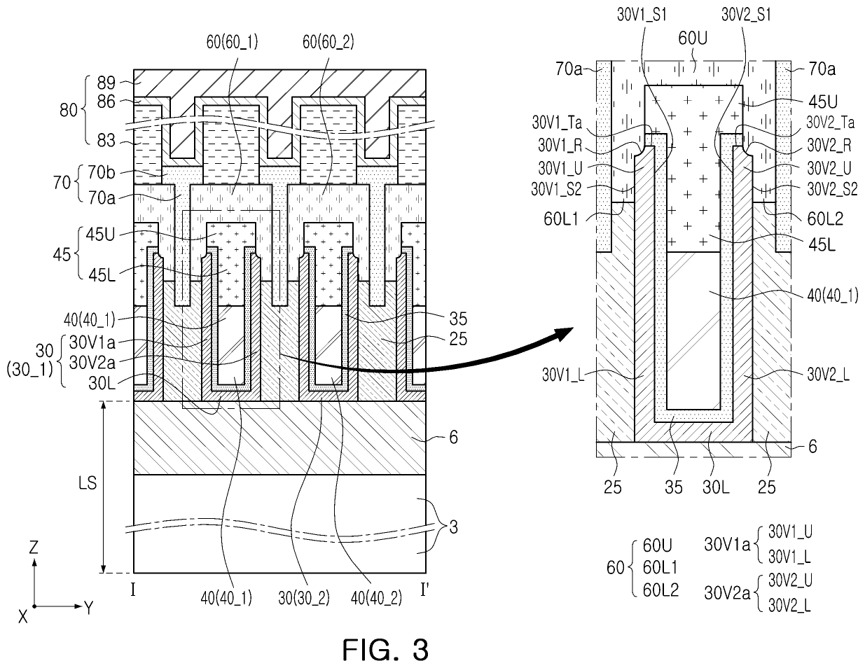

A modified example of a semiconductor device according to example embodiments will be described with reference to FIG. 3. FIG. 3 is a cross-sectional view illustrating a region taken along line I-I′ of FIG. 1 to describe a modified example of a semiconductor device according to example embodiments.

In a variant example, referring to FIG. 3, the first vertical active portion (30V1 in FIG. 2A) described above may be transformed into a first vertical active portion 30V1a having the upper surfaces 30V1_Ta and 30V1_R as in FIG. 3, and the second vertical active portion (30V2 in FIG. 2A) having the upper surface (30V2_Ta, 30V2_Tb in FIG. 2A) described above may be transformed into a second vertical active portion 30V2a with the upper surfaces 30V2_Ta and 30V2_R as in FIG. 3.

The upper surface (30V1_Ta, 30V1_R) of the first vertical active portion (30V1a) may include a first surface 30V1_Ta in contact with the gate dielectric layer 35 without contacting the conductive pad pattern 60, and a second surface 30V1_R that is recessed beyond the first surface 30V1_Ta and is in contact with the conductive pad pattern 60. The recessed second surface 30V1_R of the upper surface 30V1_Ta, 30V1_R of the first vertical active portion 30V1a may be in contact with the first lower pad portion 60L1 of the conductive pad pattern 60.

The upper surface (30V2_Ta, 30V2_R) of the second vertical active portion (30V2a) may include a third surface 30V2_Ta in contact with the gate dielectric layer 35 without contacting the conductive pad pattern 60, and a fourth surface 30V2_R that is recessed beyond the third surface 30V2_Ta and is in contact with the conductive pad pattern 60. The recessed fourth surface 30V2_R of the upper surface 30V2_Ta, 30V2_R of the second vertical active portion 30V2a may be in contact with the second lower pad portion 60L2 of the conductive pad pattern 60.

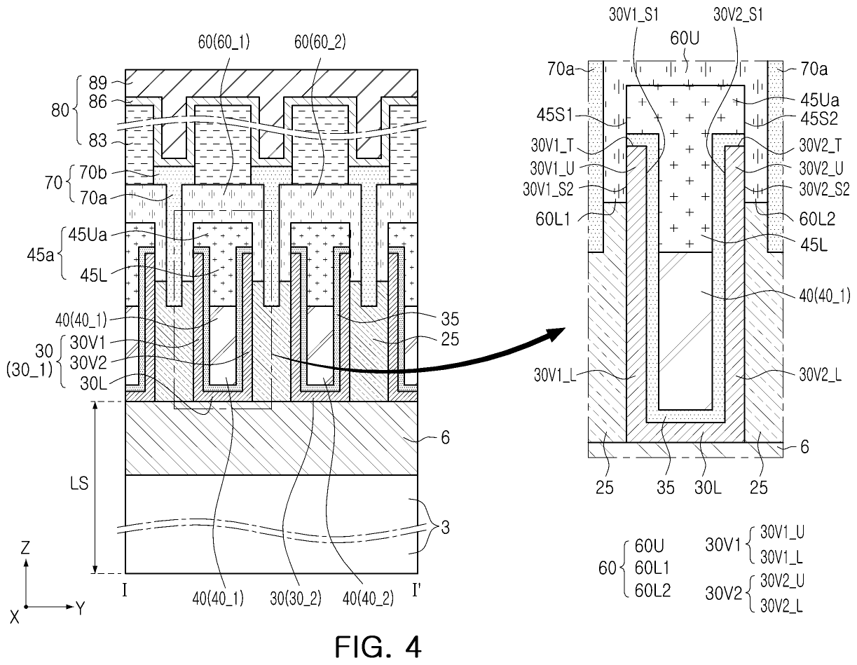

A modified example of a semiconductor device according to example embodiments will be described with reference to FIG. 4. FIG. 4 is a cross-sectional view illustrating a region taken along line I-I′ of FIG. 1 to describe a modified example of a semiconductor device according to example embodiments.

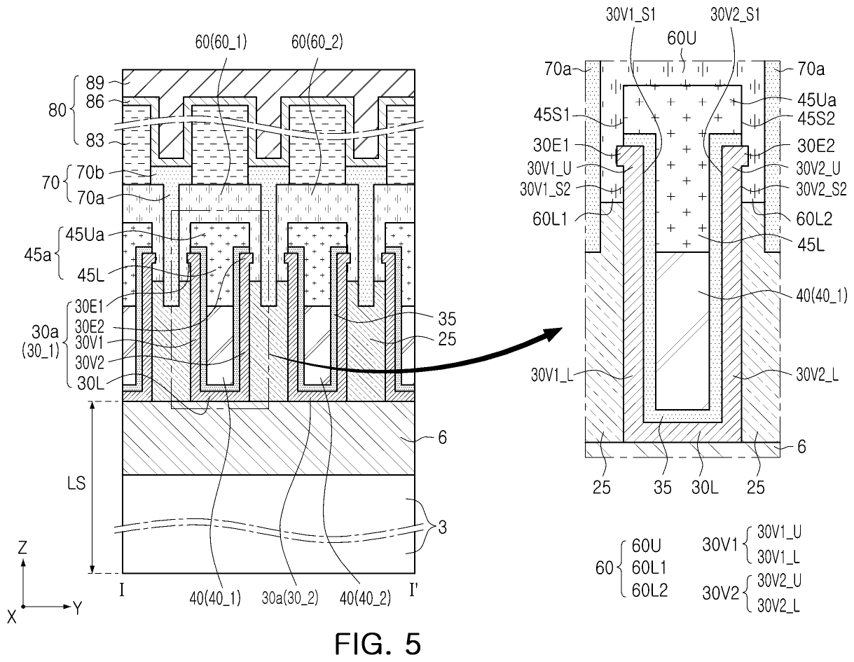

In a modified example, referring to FIG. 4, the insulating capping pattern 45 including the upper capping portion 45U described above may be transformed into an insulating capping pattern 45a including an upper capping portion 45Ua as illustrated in FIG. 5. The first side 45S1 of the upper capping portion 45Ua of the insulating capping pattern 45a may be vertically aligned with the second side surface 30V1_S2 of the first vertical active portion 30V1, and the second side 45S2 of the upper capping portion 45Ua of the insulating capping pattern 45a may be vertically aligned with the fourth side surface 30V2_S2 of the second vertical active portion 30V2.

The first lower pad portion 60L1 may contact the second side surface 30V1_S2 of the upper region 30V1_U of the first vertical active portion 30V1, and the upper surface 30V1_T of the first vertical active portion 30V1 may not contact the first lower pad portion 60L1. The upper surface 30V1_T of the first vertical active portion 30V1 may contact the gate dielectric layer 35.

The second lower pad portion 60L2 may contact the fourth side surface 30V4_S2 of the upper region 30V2_U of the second vertical active portion 30V2, and the upper surface 30V2_T of the second vertical active portion 30V2 may not contact the second lower pad portion 60L2. The upper surface 30V2_T of the second vertical active portion 30V2 may contact the gate dielectric layer 35.

A modified example of a semiconductor device according to example embodiments will be described with reference to FIG. 5. FIG. 5 is a cross-sectional view illustrating a region taken along line I-I′ of FIG. 1 to describe a modified example of a semiconductor device according to example embodiments.

In a variation, referring to FIG. 5, the above-described active patterns (30 in FIG. 2A or FIG. 4) may be modified into active patterns 30a further including extended active portions 30E1 and 30E2 as illustrated in FIG. 5.

Each of the active patterns 30a may include a first extended active portion 30E1 extending from the upper region 30V1_U of the first vertical active portion 30V1 in a direction away from the second vertical active portion 30V2, and a second extended active portion 30E2 extending from the upper region 30V2_U of the second vertical active portion 30V2 in a direction away from the first vertical active portion 30V1. Therefore, each of the active patterns 30a may include the lower active portion 30L, the first vertical active portion 30V1, the second vertical active portion 30V2, the first extended active portion 30E1 and the second extended active portion 30E2.

In each of the conductive pad patterns 60, the first lower pad portion 60L1 may contact the second side surface 30V1_S2 of the upper region 30V1_U of the first vertical active portion 30V1, and may contact the upper surface, lower surface, and side surface of the first extended active portion 30E1. In each of the conductive pad patterns 60, the second lower pad portion 60L2 may contact the fourth side surface 30V2_S2 of the upper region 30V2_U of the second vertical active portion 30V2, and may contact the upper surface, lower surface, and side surface of the second extended active portion 30E2.

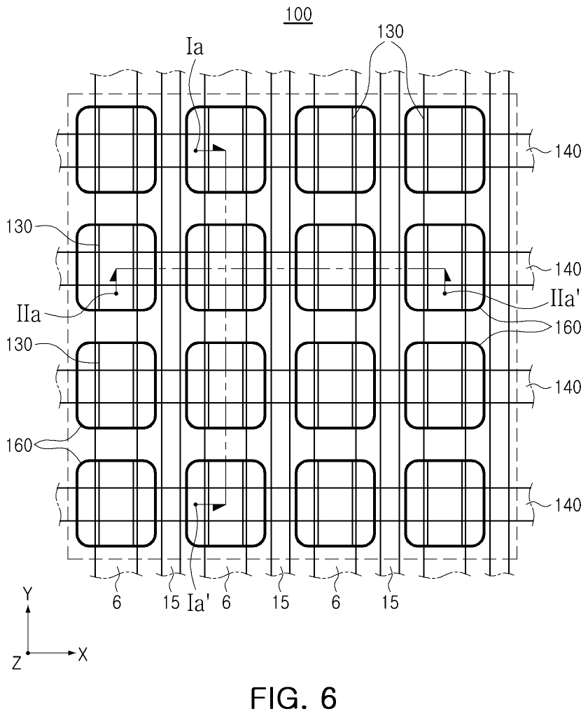

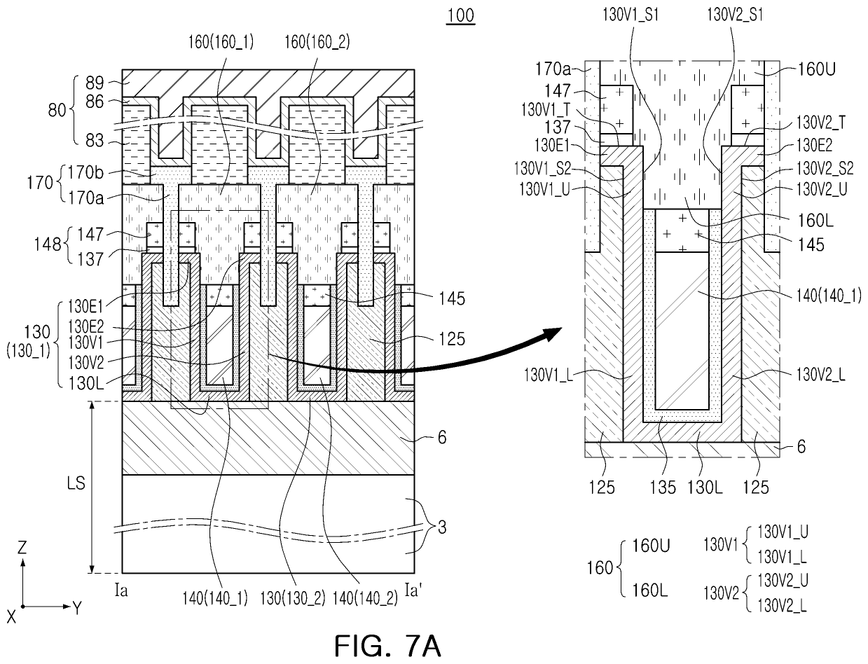

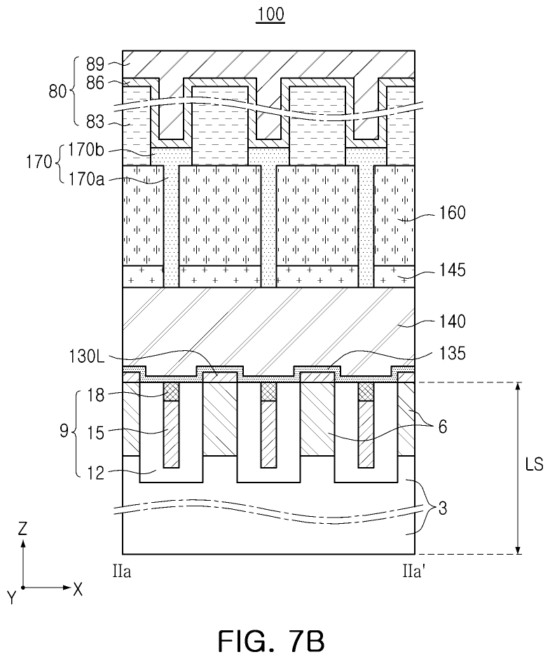

Next, with reference to FIGS. 6, 7A, and 7B, a modified example of a semiconductor device according to example embodiments will be described. Referring to FIGS. 6, 7A, and 7B, FIG. 6 is a plan view illustrating a semiconductor device according to example embodiments, FIG. 7A is a cross-sectional view conceptually illustrating the area taken along line Ia-Ia′ in FIG. 6, and FIG. 7B is a partial enlarged view of the area indicated by IIa-IIa′ in FIG. 6.

Referring to FIGS. 6, 7A, and 7B, the semiconductor device 100 according to example embodiments may include the lower structure LS described with reference to FIGS. 1, 2A, and 2B.

The semiconductor device 100 may further include insulating patterns 125 disposed on the lower structure LS. Each of the insulating patterns 125 may have a line shape extending in the second horizontal direction X. The insulating patterns 125 may be formed of an insulating material such as silicon oxide.

The semiconductor device 100 may further include active patterns 130 arranged in the first horizontal direction Y and the second horizontal direction X. The active patterns 130 may be formed of the same semiconductor material as the previously described active patterns (FIGS. 1, 2A, and 2B). The active patterns 130 may include an oxide semiconductor.

Each of the active patterns 130 may include a lower active portion 130L, a first vertical active portion 130V1, a second vertical active portion 130V2, a first extended active portion 130E1, and a second extended active portion 30E2. In each of the active patterns 130, the first vertical active portion 130V1 and the second vertical active portion 130V2 may be arranged in the first horizontal direction Y. The lower active portion 130L may be disposed on the bit line 6 and connected to the bit line 6. For example, the lower surface of the lower active portion 130L may contact the upper surface of the bit line 6. The first vertical active portion 130V1 may extend upwardly from the first side of the lower active portion 130L. The first vertical active portion 130V1 may include a first lower region 130V1_L and a first upper region 130V1_U on the first lower region 130V1_L. The second vertical active portion 130V2 may extend upwardly from the second side of the lower active portion 130L. The second vertical active portion 130V2 may include a first lower region 130V2_L and a first upper region 130V2_U on the first lower region 130V2_L.

The first extended active portion 130E1 may extend from the upper region 130V1_U of the first vertical active portion 130V1 in a direction away from the second vertical active portion 130V2. The first extended active portion 130E1 may extend in a direction away from the second vertical active portion 130V2 from the upper end of the first vertical active portion 130V1. A lower surface of the first extended active portion 130E1 may contact an upper surface of the insulating pattern 125. The second extended active portion 130E2 may extend from the upper region 130V2_U of the second vertical active portion 130V2 in a direction away from the first vertical active portion 130V1. The second extended active portion 130E2 may extend from the upper end of the second vertical active portion 230V1 in a direction away from the first vertical active portion 130V1. A lower surface of the second extended active portion 130E2 may contact an upper surface of the insulating pattern 125. The upper surfaces 130V1_T and 130V2_T of the first and second extended active portions (130E1 and 30E2 in FIG. 7A) may be flat.

The semiconductor device 100 may further include word lines 140. The word lines 140 may be gate electrodes. The word lines 140 may be the same as the word lines (40 in FIGS. 1, 2A, and 2B) described above.

The word lines 140 may be disposed on a lower level than level of the upper surfaces of the first and second vertical active portions 130V1 and 130V2. The word lines 140 may be placed at a lower level than level of the upper surfaces of the insulating patterns 125. Each of the word lines 140 may have a line shape extending in the second horizontal direction X. The word lines 140 may include a first word line 140_1 and a second word line 140_2 that are adjacent to each other in the first horizontal direction Y. The word lines 140 may be disposed on the lower active portions 130L and between the first vertical active portions 130V1 and the second vertical active portions 130V2.

The semiconductor device 100 may further include insulating capping patterns 145 on the word lines 140. The insulating capping patterns 145 may be disposed between the first vertical active portions 130V1 and the second vertical active portions 130V2. The insulating capping patterns 145 may contact upper surfaces of the word lines 140. The insulating capping patterns 145 may be disposed at a lower level than level of the first and second extended active portions 130E1 and 130E2.

The semiconductor device 100 may further include gate dielectric layers 35 disposed between the active patterns 130 and the word lines 140 and between the active patterns 130 and the insulating capping patterns 145. The gate dielectric layers 35 may contact the active patterns 30, the word lines 40, and the insulating capping patterns 45.

The semiconductor device 100 may further include a dummy insulating structure 148 disposed on the first and second extended active portions 130E1 and 130E2 of the active patterns 130. The dummy insulating structure 148 may cover a portion of the upper surfaces 130V1_T and 130V2_T of the first and second extended active portions 130E1 and 130E2. The dummy insulating structure 148 may include a dummy dielectric layer 137 and a dummy capping insulating pattern 147 that are sequentially stacked. The dummy dielectric layer 137 may be formed of the same material as the gate dielectric layer 135 and may have the same thickness as the gate dielectric layer 135. The dummy capping insulating pattern 147 may be formed of the same material as the insulating capping patterns 145.

The semiconductor device 100 may further include conductive pad patterns 160 that vertically overlap the word lines 140 and are connected to the active patterns 130. The conductive pad patterns 160 may be formed of the same material as the conductive pad patterns (60 in FIGS. 1, 2A, and 2B) described above. The conductive pad patterns 160 may be placed at a higher level than level of the word lines 140. Each of the conductive pad patterns 160 may be connected to the upper region 130V1_U of the first vertical active portion 130V1 and the upper region 130V2_U of the second vertical active portion 130V2. Each of the conductive pad patterns 160 may include an upper pad portion 160U, and a lower pad portion 160L extending downwardly from the center area of the upper pad portion 160U and connected to the upper region 130V1_U of the first vertical active portion 130V1 and the upper region 130V2_U of the second vertical active portion 130V2. The width of each of the conductive pad patterns 160 in the first horizontal direction Y may be greater than the width of each of the word lines 140 in the first horizontal direction Y.

The conductive pad patterns 160 may include a first conductive pad pattern 160_1 and a second conductive pad pattern 160_2 adjacent to each other in the first horizontal direction Y. The active patterns 130 may include a first active pattern 130_1 and a second active pattern 130_2 adjacent to each other in the first horizontal direction Y.

The first conductive pad pattern 160_1 may be connected to the upper regions 130V1_U and 130V2_U of the first and second vertical active portions 130V1 and 130V2 of the first active pattern 130_1. The second conductive pad pattern 160_2 may be connected to the upper regions 130V1_U and 130V2_U of the first and second vertical active portions 130V1 and 130V2 of the second active pattern 130_2.

In each of the active patterns 130, the first vertical active portion 130V1 may have a first side surface 130V1_S1 facing the second vertical active portion 130V2 and a second side surface 130V1_S2 facing the first side 130V1_S1, and the second vertical active portion 130V2 may have a third side surface 130V2_S1 facing the first vertical active portion 130V1 and a fourth side surface 130V2_S2 facing the third side surface 130V2_S1.

In each of the conductive pad patterns 160, the lower pad portion 160L may contact the first side 130V1_S1 of the first vertical active portion 130V1 and the third side surface 30V2_S1 of the second vertical active portion 130V2.

Each of the conductive pad patterns 160 may contact at least a portion of the upper surfaces 130V1_T and 103V2_T of the first and second vertical active portions 130V1 and 130V2. For example, in the first active pattern 130_1 and the first conductive pad pattern 160_1 connected to each other, the first conductive pad pattern 160_1 may be in contact with at least a portion of the upper surface 130V1_T of the first vertical active portion 130V1 and at least a portion of the upper surface 130V2_T of the second vertical active portion 130V2.

The upper surface 130V1_T of the first extended active portion 130E1 may include a portion in contact with the dummy insulating structure 148 and a portion in contact with the conductive pad pattern 160. The upper surface 130V2_T of the second extended active portion 130E2 may include a portion in contact with the dummy insulating structure 148 and a portion in contact with the conductive pad pattern 160.

The semiconductor device 100 may further include an insulating structure 170 disposed on the upper surfaces of the conductive pad patterns 160, disposed between the conductive pad patterns 160, and extending downwardly to pass between the active patterns 130.

The insulating structure 170 may include an insulating separation portion 170a and an insulating capping portion 170b.

The insulating separation portion 170a may be disposed between the conductive pad patterns 60 arranged in the first horizontal direction Y, penetrate the dummy insulating structure 148, extend downwardly, pass between the active patterns 130 to extend into the insulating patterns 125, and may be disposed between the conductive pad patterns 160 arranged in the second horizontal direction X and between the insulating capping patterns 145.

The insulating capping portion 170b is disposed at a higher level than level of the conductive pad patterns 160 and may be disposed on upper surfaces of the conductive pad patterns 160. The conductive pad patterns 160 may be spaced apart from each other by the insulating separation portion 170a. In the cross-sectional structure in the first horizontal direction Y as illustrated in FIG. 7A, the lower surface of the insulating separation portion 170a may contact the insulating patterns 125, and in the cross-sectional structure in the second horizontal direction X as illustrated in FIG. 7B, the lower surface of the insulating separation portion 170a may contact the word lines 140. The insulating separation portion 170a may contact side surfaces of the extended active portions 130E1 and 130E2 of the active patterns 130. The lower surface of the insulating separation portion 170a may be disposed at a lower level than level of the extended active portions 130E1 and 130E2.

The semiconductor device 100 may further include the same information storage structure 80 as described above. The information storage structure 80 may be a cell capacitor capable of storing information in a memory device such as DRAM. For example, the information storage structure 80 may include first electrodes 83 penetrating the insulating capping portion 170b, connected to the conductive pad patterns 160 and extending upwardly, a dielectric layer 86 disposed on the first electrodes 83 and the insulating capping portion 170b, and a second electrode 89 on the dielectric layer 86.

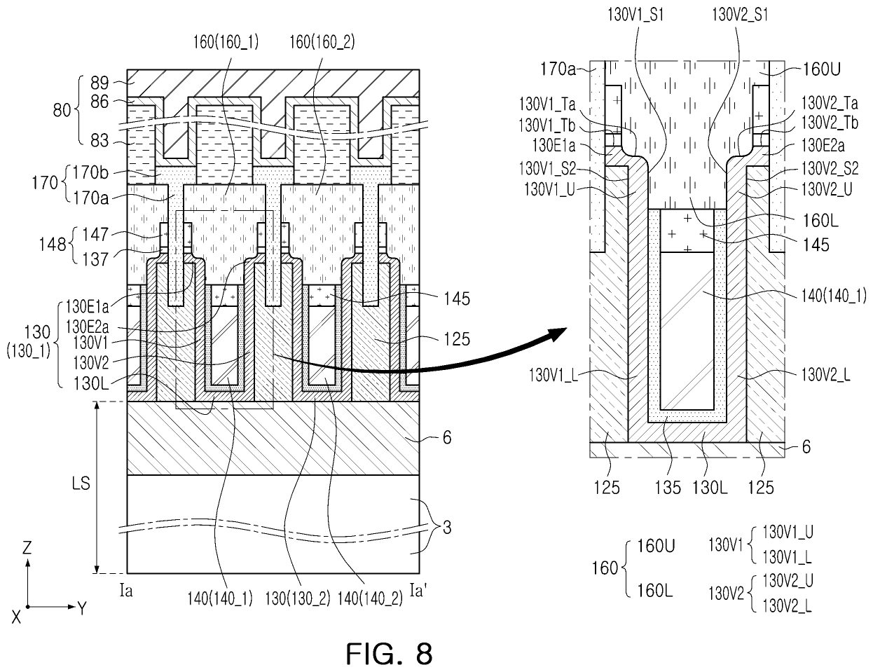

A modified example of a semiconductor device according to example embodiments will be described with reference to FIG. 8. FIG. 8 is a cross-sectional view illustrating a region taken along line Ia-Ia′ of FIG. 6 to describe a modified example of a semiconductor device according to example embodiments.

In a variation, referring to FIG. 8, the first and second extended active portions (130E1 and 30E2 in FIG. 7A) described above may be modified into the first and second extended active portions 130E1a and 130E2a as illustrated in FIG. 8. The upper surfaces 130V1_Ta and 130V1_Tb of the first extended active portion 130E1a may include a recessed first surface 130V1_Ta and a flat second surface 130V1_Tb, and the upper surfaces 130V2_Ta and 130V2_Tb of the second extended active portion 130E2a may include a recessed third surface 130V2_Ta and a flat fourth surface 130V2_Tb. In the case of the upper surfaces 130V1_Ta and 130V1_Tb of the first extended active portion 130E1a, the recessed first surface 130V1_Ta may be recessed than the flat second surface 130V1_Tb, and in the case of the upper surfaces 130V2_Ta and 130V2_Tb of the second extended active portion 130E2a, the recessed third surface 130V2_Ta may be recessed more than the flat fourth surface 130V2_Tb. The recessed first surface 130V1_Ta of the upper surface 130V1_Ta, 130V1_Tb of the first extended active portion 130E1a, and the recessed third surface 130V2_Ta of the upper surface 130V2_Ta, 130V2_Tb of the second extended active portion 130E2a, may contact the conductive pad pattern 160.

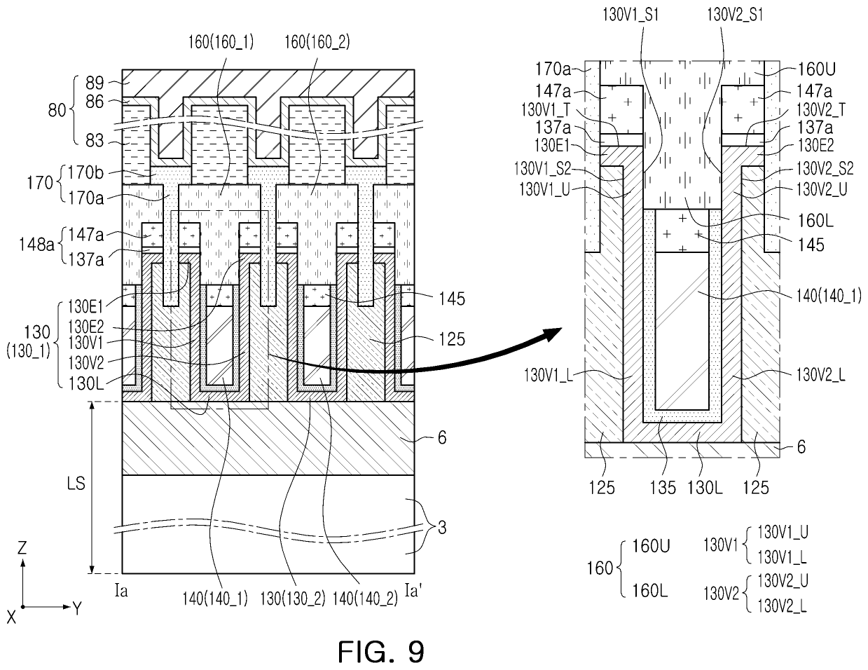

A modified example of a semiconductor device according to example embodiments will be described with reference to FIG. 9. FIG. 9 is a cross-sectional view illustrating a region taken along line Ia-Ia′ of FIG. 6 to describe a modified example of a semiconductor device according to example embodiments.

In a modified example, referring to FIG. 9, the previously described dummy insulating structure 148 in FIG. 7A may be transformed into the dummy insulating structure 148a as illustrated in FIG. 9. The dummy insulating structure 148a may cover or overlap the entire upper surface 130V1_T and 130V2_T of the active pattern 130. The dummy insulating structure 148a may include a dummy dielectric layer 137a and a dummy capping insulating layer 147a corresponding to the previously described dummy dielectric layer (137 in FIG. 7A) and the dummy capping insulating layer (147 in FIG. 7A), respectively. The lower pad portion 160L1 of the conductive pad pattern 160 may contact the first side 130V1_S1 of the first vertical active portion 130V1 and the third side surface 30V2_S1 of the second vertical active portion 130V2. The upper surfaces (130V1_T, 130V2_T) of the active pattern 130 may not be in contact with the conductive pad pattern 160.

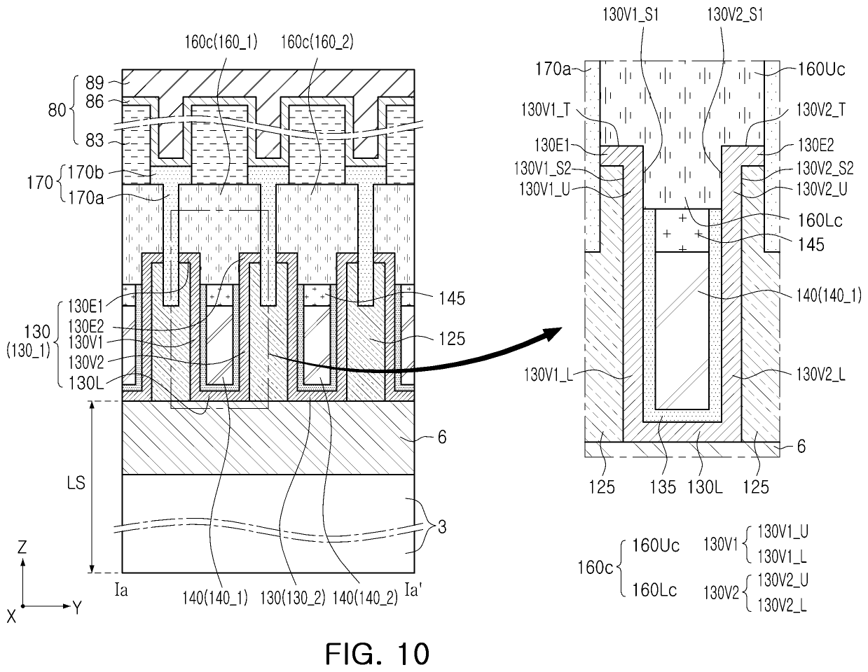

A modified example of a semiconductor device according to example embodiments will be described with reference to FIG. 10. FIG. 10 is a cross-sectional view illustrating a region taken along line Ia-Ia′ of FIG. 6 to describe a modified example of a semiconductor device according to example embodiments.

In a modified example, referring to FIG. 10, the dummy insulating structure (148 in FIG. 7A) described above may be omitted, and the conductive pad pattern (160 in FIG. 7A) described above may be transformed into a conductive pad pattern 160c that contacts the first and second extended active portions 130E1 and 130E2 of the active pattern 130, as illustrated in FIG. 10.

The conductive pad pattern 160c may include an upper pad portion 160Uc and a lower pad portion 160Lc extending downwardly from the center area of the upper pad portion 160Uc. The upper pad portion 160Uc may contact the first and second extended active portions 130E1 and 130E2 of the active pattern 130, and the lower pad portion 160Lc may contact the first side 130V1_S1 of the first vertical active portion 130V1 and the third side surface 30V2_S1 of the second vertical active portion 130V2.

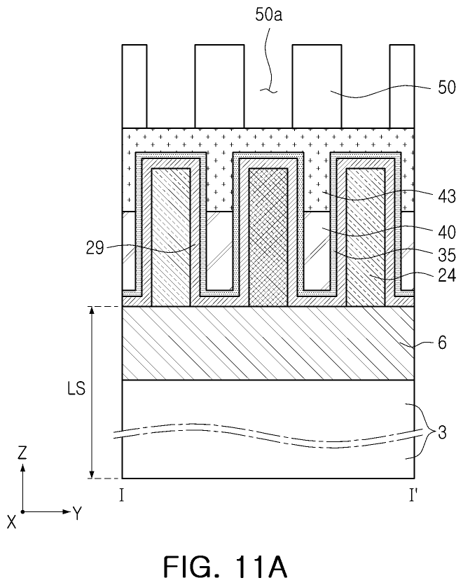

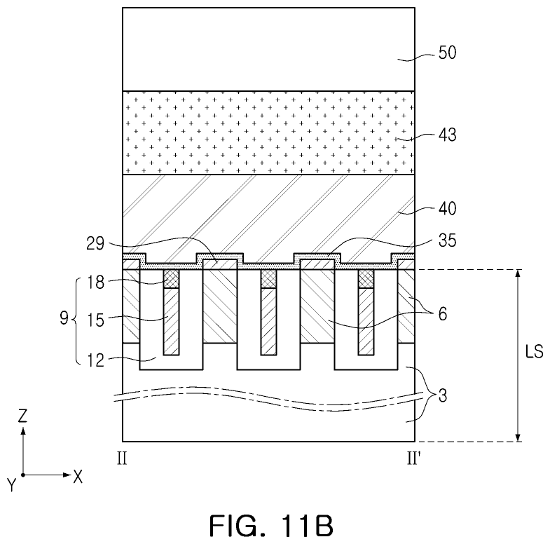

Next, an example of a method of forming a semiconductor device according to example embodiments will be described with reference to FIG. 1 and FIGS. 11A, 11B, 12, 13A, 13B, 14A, and 14B. In FIGS. 11A, 11B, 12, 13A, 13B, 14A, and 14B, FIGS. 11A, 12, 13A, and 14A are cross-sectional views illustrating the area taken along line I-I′ of FIG. 1, and FIGS. 11B, 13B, and 14B are cross-sectional views illustrating the area taken along line II-II′ in FIG. 1.

Referring to FIGS. 1, 11A, and 11B, the lower structure LS may be formed. Forming the lower structure LS may include forming bit lines 6 on the base 3 and forming a shield structure 9 between the bit lines 6. The bit lines 6 may be conductive lines. Each of the bit lines 6 may have a line shape extending in the first horizontal direction Y. Forming the shield structure 9 may include forming a shield insulating layer 12 covering the inner wall of the space between the conductive lines 6, and forming a shield conductive line 15 and a shield insulating capping pattern 18 sequentially laminated on the shield insulating layer 12.

Preliminary insulating patterns 24 may be formed on the lower structure LS. Each of the preliminary insulating patterns 24 may have a line shape extending in a second horizontal direction X perpendicular to the first horizontal direction Y.

A material layer covering, overlapping, or on the lower structure LS and the preliminary insulating patterns 24 may be formed, and the material layer may be patterned to form material patterns 29. Each of the material patterns 29 extends in the first horizontal direction Y and may cover the lower structure LS and the preliminary insulating patterns 24. The material patterns 29 may cover, overlap, or be on the upper and side surfaces of the preliminary insulating patterns 24 and the lower structure LS between the preliminary insulating patterns 24. The material patterns 29 may be spaced apart from each other in the second horizontal direction X. The material patterns 29 may be formed of a semiconductor material such as an oxide semiconductor.

A gate dielectric layer 35 may be formed to conformally cover, overlap, or be on the lower structure LS, the preliminary insulating patterns 24, and the material patterns 29.

On the gate dielectric layer 35, word lines 40 may be formed to partially fill the space between the preliminary insulating patterns 24. The word lines 40 may be gate electrodes.

A capping layer 43 may be formed on the gate dielectric layer 35 and the word lines 40. First mask patterns 50 having openings 50a may be formed on the capping layer 43. The first mask patterns 50 may vertically overlap the word lines 40 and may be formed to have a width larger than the word lines 40. The openings 50a may vertically overlap the preliminary insulating patterns 24.

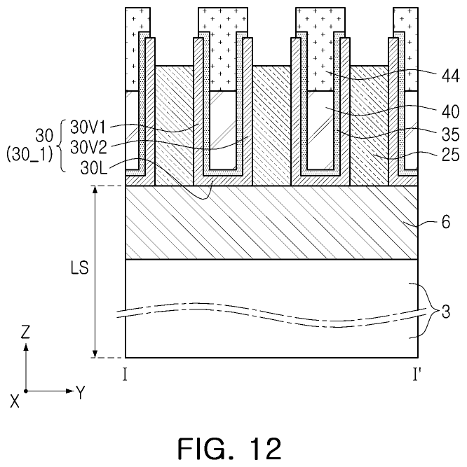

Referring to FIGS. 1 and 12, as an etching process is performed using the first mask patterns 50 as an etch mask, the capping layer 43, the gate dielectric layer 35, and the material patterns 29 may be sequentially etched, and then the preliminary insulating patterns 24 may be partially etched. The capping layer 43 may be etched to form capping lines 44, the material patterns 29 are etched to form active patterns 30, and the preliminary insulating patterns 24 may be partially etched to form insulating patterns 25 with a reduced height.

Each of the capping lines 44 may have a line shape extending in the second horizontal direction X. The capping lines 44 may be formed on the word lines 40. Each of the active patterns 30 may include a lower active portion 30L connected to the upper surface of the bit line 6, a first vertical active portion 30V1 extending upwardly from the first side of the lower active portion 30L, and a second vertical active portion 30V2 extending upwardly from the second side of the lower active portion 30L. The insulating patterns 25 may be disposed at a higher level than level of the upper surfaces of the word lines 40 and may have upper surfaces disposed at a lower level than the level of upper ends of the active patterns 30. Accordingly, upper regions of the first and second vertical active portions 30V1 and 30V2 of the active patterns 30 may be exposed by the insulating patterns 25. The first mask patterns 50 may be removed.

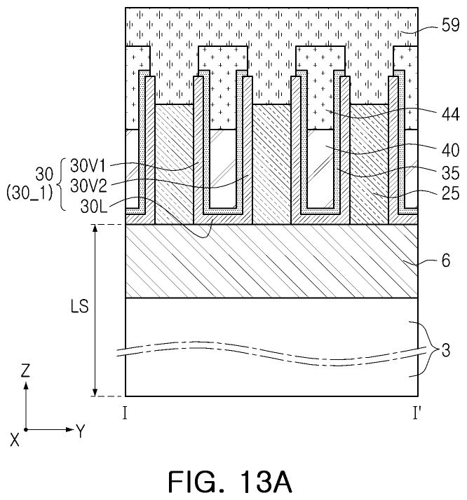

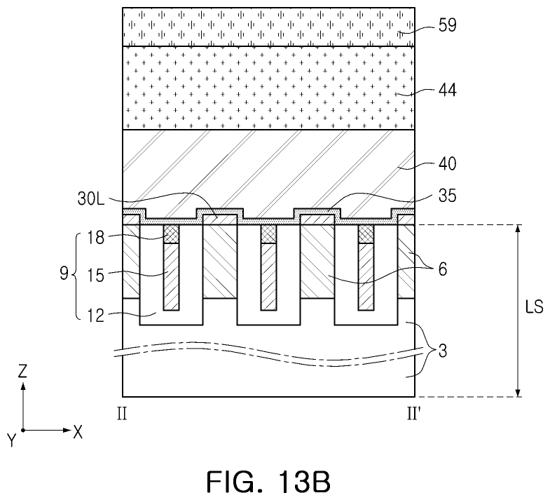

Referring to FIGS. 1, 13A, and 13B, a conductive pad layer 59 may be formed on the insulating patterns 25, the active patterns 30, and the capping lines 44. The conductive pad layer 59 may contact upper regions of the first and second vertical active portions 30V1 and 30V2 of the active patterns 30 exposed by the insulating patterns 25.

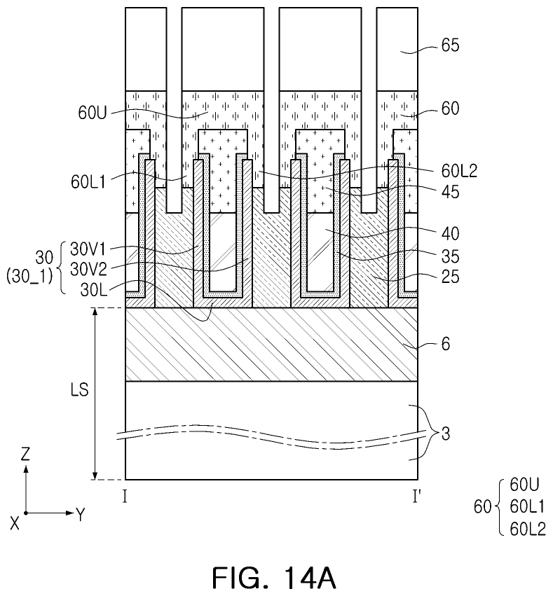

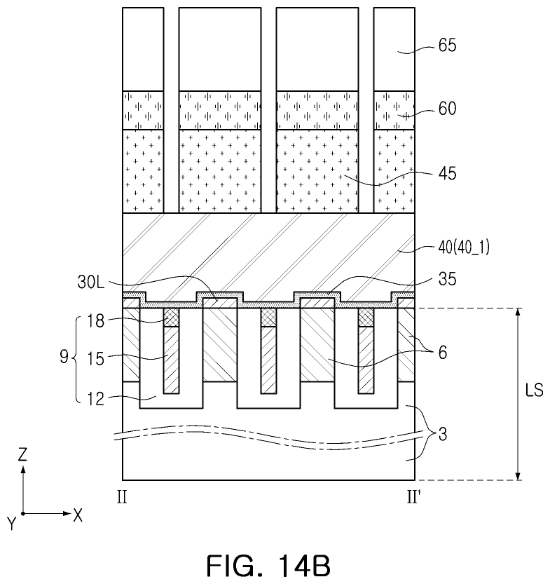

Referring to FIGS. 1, 14A, and 14B, a second mask pattern 65 may be formed on the conductive pad layer 59. An etching process using the second mask pattern 65 as an etch mask may be performed to etch the conductive pad layer 59 and the capping lines 44. The conductive pad layer 59 may be etched to form conductive pad patterns 60, and the capping lines 44 may be etched to form insulating capping patterns 45.

Each of the conductive pad patterns 60 may include an upper pad portion 60U, a first lower pad portion 60L1 extending downwardly from the first side of the upper pad portion 60U and connected to an upper region of the first vertical active portion 30V1, and a second lower pad portion 60L2 extending downwardly from the second side of the upper pad portion 60U and connected to the upper region of the second vertical active portion 30V2. Each of the insulating capping patterns 45 may include an upper capping portion disposed at a higher level than level of the active pattern 30 and a lower capping portion extending downwardly from the center of the upper capping portion and contacting the upper surface of the word line 40. The insulating capping pattern 45 may include at least one vertically overlapping portion of the first and second vertical active portions 30V1 and 30V2.

Referring again to FIGS. 1, 2A, and 2B, after removing the second mask pattern 65, the insulating structure 70 may be formed. The insulating structure 70 may include an insulating separation portion 70a and an insulating capping portion 70b. The insulating separation portion 70a may extend into the insulating patterns 25 while partially or completely filling a gap between the conductive pad patterns 60 arranged in the first horizontal direction Y, and may partially or completely fill a gap between the conductive pad patterns 60 and the insulating capping patterns 45 arranged in the second horizontal direction X. The insulating capping portion 70b may be disposed at a higher level than level of the conductive pad patterns 60 and may be formed on upper surfaces of the conductive pad patterns 60.

An information storage structure 80 may be formed. The information storage structure 80 may be a cell capacitor capable of storing information in a memory device such as DRAM. For example, the information storage structure 80 may include first electrodes 83 penetrating the insulating capping portion 70b, connected to the conductive pad patterns 60 and extending upwardly, a dielectric layer 86 disposed on the first electrodes 83 and the insulating capping portion 70b, and a second electrode 89 on the dielectric layer 86.

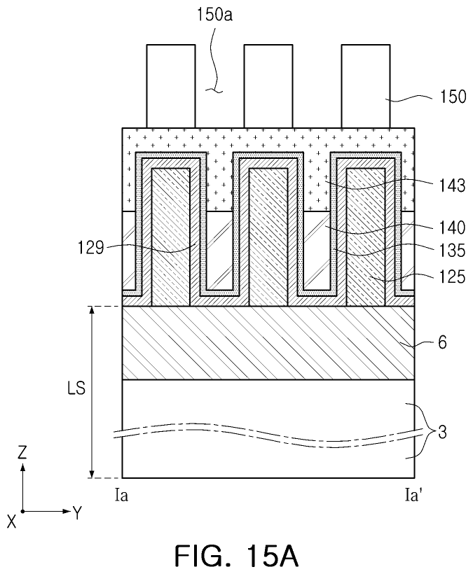

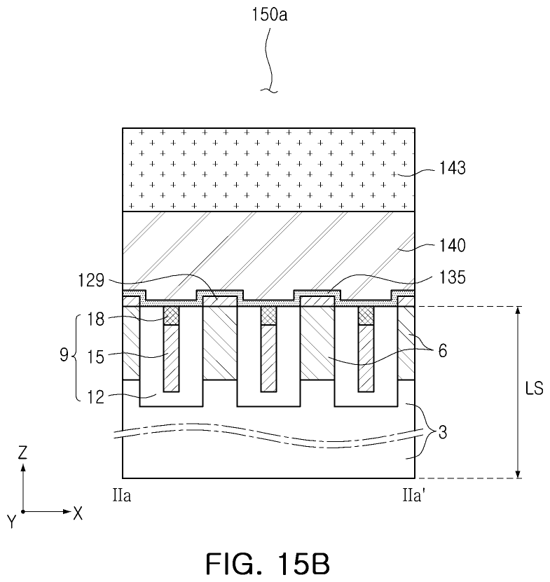

Next, another example of a method of forming a semiconductor device according to example embodiments will be described with reference to FIG. 6 and FIGS. 15A, 15B, 16A, 16B, 17A, 17B, 18A, and 18B. In FIGS. 15A, 15B, 16A, 16B, 17A, 17B, 18A, and 18B, FIGS. 15A, 16A, 17A, and 18A are cross-sectional views illustrating the area taken along line Ia-Ia′ of FIG. 6, and FIGS. 15b, 16b, 17b, and 18b are cross-sectional views illustrating the area taken along line IIa-IIa′ in FIG. 6.

Referring to FIGS. 6, 15A, and 15B, the lower structure LS as illustrated in FIGS. 11A and 11B may be formed. Insulating patterns 125 may be formed on the lower structure LS. Each of the insulating patterns 125 may have a line shape extending in a second horizontal direction X perpendicular to the first horizontal direction Y.

A material layer covering, overlapping, of on the lower structure LS and the insulating patterns 125 may be formed, and the material layer may be patterned to form material patterns 129. The material patterns 129 may be the same as the material patterns 29 described in FIGS. 11A and 11B.

A gate dielectric layer 135 may be formed to conformally cover or overlap the lower structure LS, the insulating patterns 125, and the material patterns 129. On the gate dielectric layer 135, word lines 140 may be formed to partially fill the space between the insulating patterns 125. The word lines 140 may be gate electrodes.

A capping layer 143 may be formed on the gate dielectric layer 135 and the word lines 140. First mask patterns 150 having openings 150a may be formed on the capping layer 143. The first mask patterns 150 may vertically overlap the insulating patterns 125. The openings 150a may vertically overlap the word lines 140. The openings 150a may be formed to have a width larger than the width of the word lines 40.

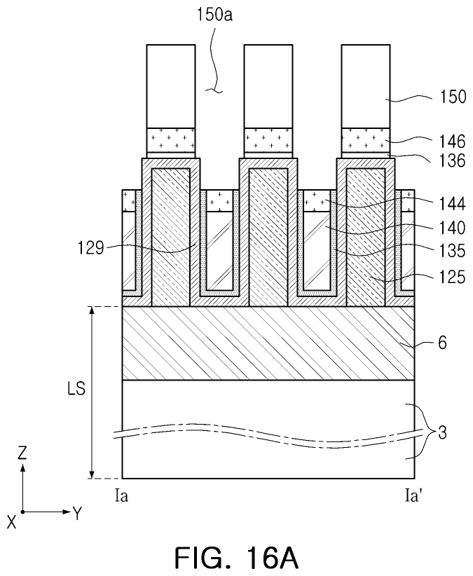

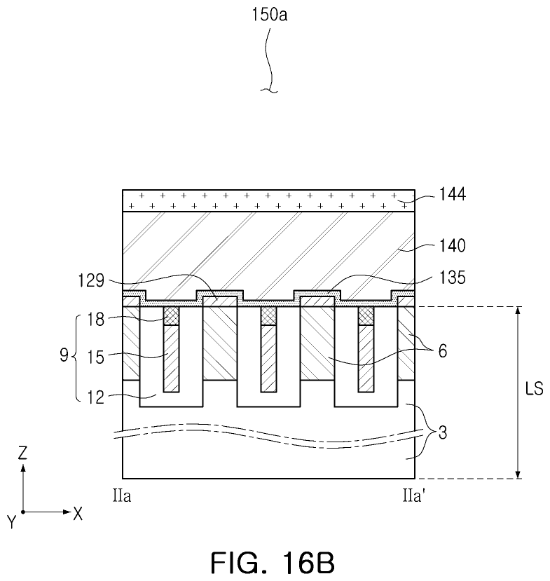

Referring to FIGS. 6, 16A, and 16B, an etching process using the first mask patterns 150 as an etch mask may be performed to sequentially etch the capping layer 143 and the gate dielectric layer 135, and side surfaces of upper regions of the material patterns 129 may be exposed.

The capping layer 143 may be etched to form dummy capping lines 146 and capping lines 144. The capping lines 144 may be formed on the word lines 140 and may be formed at a lower level than level of the upper surfaces of the material patterns 129. The dummy capping lines 146 may vertically overlap upper surfaces of the insulating patterns 125. The dummy capping lines 146 may be placed at a higher level than level of the capping lines 144. Among the gate dielectric layers 135, the gate dielectric layers located in areas that overlap perpendicularly to the upper surfaces of the insulating patterns 125 may be formed into dummy dielectric lines 136 by the etching process. Lower surfaces of the dummy capping lines 146 may contact upper surfaces of the dummy dielectric lines 136.

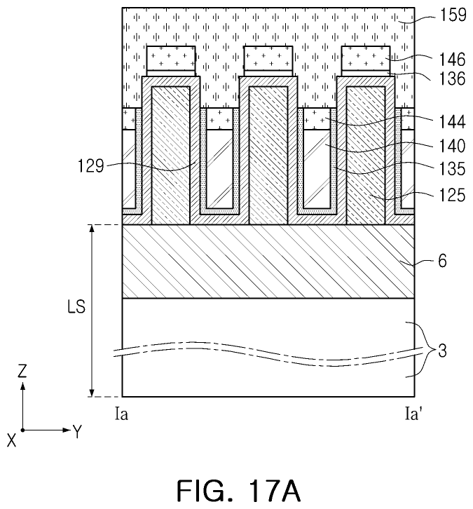

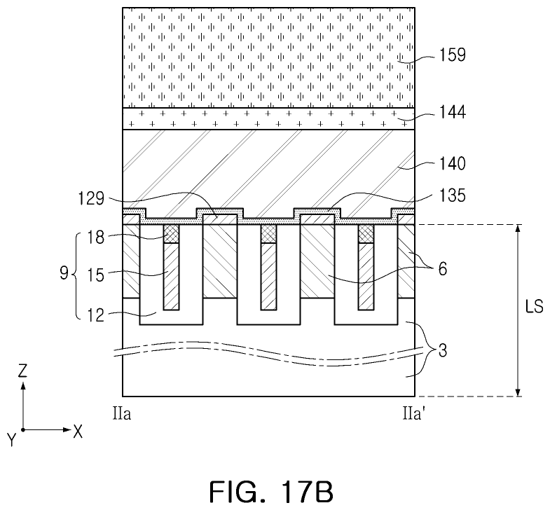

Referring to FIGS. 6, 17A, and 17B, after removing the first mask patterns 150, a conductive pad layer 159 may be formed. The conductive pad layer 159 may cover, overlap, or be on the dummy capping lines 146 and the capping lines 144 and may contact side surfaces of upper regions of the material patterns 129.

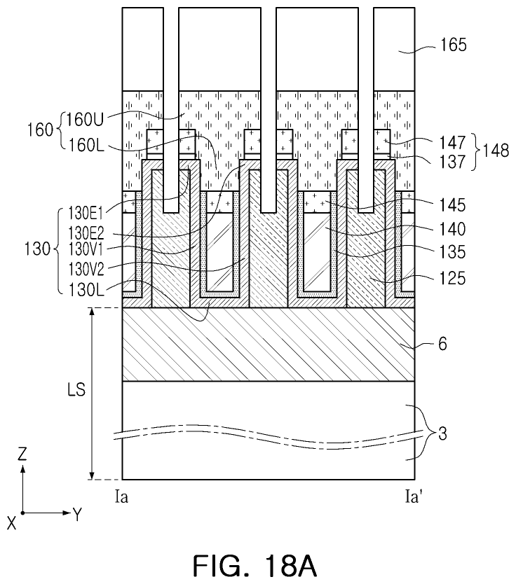

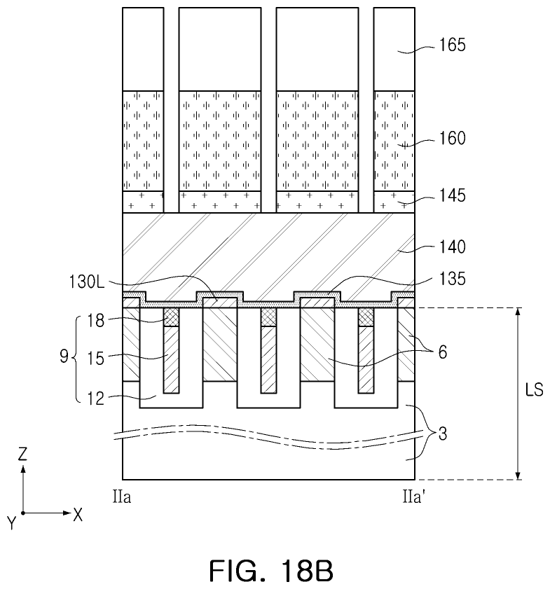

Referring to FIGS. 6, 18A, and 18B, a second mask pattern 165 may be formed on the conductive pad layer 159. As an etching process is performed using the second mask pattern 165 as an etch mask, the conductive pad layer 159, the dummy capping lines 46, the dummy dielectric lines 136, the material patterns 129, and the capping lines 144 may be etched.

The conductive pad layer 159 may be etched to form conductive pad patterns 160, the dummy capping lines 146 may be etched to form dummy capping insulating patterns 147, the dummy dielectric lines 136 may be etched to form dummy dielectric layers 137, the material patterns 129 may be etched to form active patterns 130 spaced apart from each other, and the capping lines 144 may be etched to form insulating capping patterns 145. The dummy insulating structure 148 may include the dummy dielectric layer 137 and the dummy capping insulating pattern 147 that are sequentially stacked.

Each of the active patterns 130 may include a lower active portion 130L, a first vertical active portion 130V1, a second vertical active portion 130V2, a first extended active portion 130E1, and a second extended active portion 30E2. In each of the active patterns 130, the lower active portion 130L may be formed on the bit line 6, the first vertical active portion 130V1 may extend upwardly from the first side of the lower active portion 130L, the second vertical active portion 130V2 may extend upwardly from the second side of the lower active portion 130L, the first extended active portion 130E1 may extend from an upper region of the first vertical active portion 130V1 in a direction away from the second vertical active portion 130V2, and the second extended active portion 130E2 may extend from an upper region of the second vertical active portion 130V2 in a direction away from the first vertical active portion 130V1. Lower surfaces of the first and second extended active portions 130E1 and 130E2 may contact upper surfaces of the insulating patterns 125.

Each of the conductive pad patterns 160 may be connected to an upper region of the first vertical active portion 130V1 and an upper region of the second vertical active portion 130V2. Each of the conductive pad patterns 160 may include an upper pad portion 160U, and a lower pad portion 160L extending downwardly from the middle region of the upper pad portion 160U and connected to the upper region of the first vertical active portion 130V1 and the upper region of the second vertical active portion 130V2. For example, the lower pad portion 160L may contact a side surface of the upper region of the first vertical active portion 130V1 and a side surface of the upper region of the second vertical active portion 130V2.

Referring again to FIGS. 1, 7A, and 7B, after removing the second mask pattern 165, the insulating structure 170 may be formed. The insulating structure 170 may include an insulating separation portion 170a and an insulating capping portion 170b.

The insulating structure 170 may include an insulating separation portion 170a and an insulating capping portion 170b. The insulating separation portion 170a may partially or completely fill space between the conductive pad patterns 60 arranged in the first horizontal direction Y, extend downwardly, pass between the active patterns 130 while extending into the insulating patterns 125, and fill space between the conductive pad patterns 160 arranged in the second horizontal direction X and between the insulating capping patterns 145. The insulating capping portion 170b is disposed at a higher level than level of the conductive pad patterns 160 and may be disposed on upper surfaces of the conductive pad patterns 160. The conductive pad patterns 160 may be spaced apart from each other by the insulating separation portion 170a. The insulating separation portion 170a may contact side surfaces of the extended active portions 130E1 and 130E2 of the active patterns 130. The lower surface of the insulating separation portion 170a may be formed at a lower level than level of the extended active portions 130E1 and 130E2.

An information storage structure 180 may be formed. The information storage structure 180 may be a cell capacitor capable of storing information in a memory device such as DRAM. For example, the information storage structure 180 may include first electrodes 83 penetrating through the insulating capping portion 170b, connected to the conductive pad patterns 160 and extending upwardly, a dielectric layer 86 disposed on the first electrodes 83 and the insulating capping portion 70b, and a second electrode 89 on the dielectric layer 86.

As set forth above, according to example embodiments, a semiconductor device including an active pattern containing first and second vertical active portions on both sides of one gate electrode, and a conductive pad pattern connected to upper regions of the first and second vertical active portions may be provided. The first and second vertical active portions may be vertical channel regions of one transistor. Since the conductive pad pattern may contact upper regions of the first and second vertical active portions of the active pattern, contact resistance between the conductive pad pattern and the active pattern may be improved. Therefore, the Ion (ON-Current) of the transistor may be improved and the channel resistance and contact resistance may be reduced, thereby improving the performance of the semiconductor device.

While example embodiments have been illustrated and described above, it will be apparent to those skilled in the art that modifications and variations could be made without departing from the scope of the present inventive concept as defined by the appended claims.

1. A semiconductor device comprising:
a bit line;
an active pattern on the bit line, and including a lower active portion electrically connected to the bit line, a first vertical active portion extending from the lower active portion, and a second vertical active portion extending from the lower active portion, wherein the first vertical active portion and the second vertical active portion are spaced apart from one another;
a word line between a lower region of the first vertical active portion and a lower region of the second vertical active portion; and
a conductive pad pattern electrically connected to an upper region of the first vertical active portion and an upper region of the second vertical active portion.

2. The semiconductor device of claim 1, wherein the active pattern includes an oxide semiconductor.

3. The semiconductor device of claim 1, wherein the bit line extends in a first horizontal direction,
wherein the word line extends in a second horizontal direction perpendicular to the first horizontal direction,
wherein the first vertical active portion and the second vertical active portion are spaced apart in the first horizontal direction, and
wherein the conductive pad pattern comprises:
an upper pad portion;
a first lower pad portion extending from the upper pad portion and electrically connected to the upper region of the first vertical active portion; and
a second lower pad portion extending from the upper pad portion and electrically connected to the upper region of the second vertical active portion.

4. The semiconductor device of claim 3, wherein the first vertical active portion has a first side surface facing the second vertical active portion and a second side surface opposing the first side surface,
wherein the second vertical active portion has a third side surface facing the first vertical active portion and a fourth side surface opposing the third side surface,
wherein the first lower pad portion contacts the second side surface of the first vertical active portion, and
wherein the second lower pad portion contacts the fourth side surface of the second vertical active portion.

5. The semiconductor device of claim 4, wherein at least a portion of an upper surface of the first vertical active portion is in contact with the first lower pad portion.

6. The semiconductor device of claim 1, wherein an upper surface of the first vertical active portion has a first surface not in contact with the conductive pad pattern, and a second surface further recessed than the first surface and is in contact with the conductive pad pattern.

7. The semiconductor device of claim 1, further comprising an insulating capping pattern between an upper surface of the word line and the conductive pad pattern,
wherein the insulating capping pattern comprises:
an upper capping portion that is a greater first distance from the bit line than a second distance of the active pattern from the bit line; and
a lower capping portion extending from a central area of the upper capping portion and contacting the upper surface of the word line, and
wherein the upper capping portion includes a portion vertically overlapping at least one of the first and second vertical active portions.

8. The semiconductor device of claim 1, wherein the active pattern further comprises:
a first extended active portion extending from an upper region of the first vertical active portion in a direction away from the second vertical active portion; and
a second extended active portion extending from an upper region of the second vertical active portion in a direction away from the first vertical active portion.

9. The semiconductor device of claim 8, wherein the conductive pad pattern comprises:
an upper pad portion;
a first lower pad portion extending from the upper pad portion and contacting an upper surface, a lower surface and a side surface of the first extended active portion; and
a second lower pad portion extending from the upper pad portion and contacting an upper surface, a lower surface and a side surface of the second extended active portion.

10. The semiconductor device of claim 8, wherein the first vertical active portion has a first side surface facing the second vertical active portion and a second side surface opposing the first side surface,
wherein the second vertical active portion has a third side surface facing the first vertical active portion and a fourth side surface opposing the third side surface, and
wherein the conductive pad pattern comprises:
an upper pad portion; and
a lower pad portion extending from a central area of the upper pad portion and contacting the first side surface of the first vertical active portion and the third side surface of the second vertical active portion.

11. The semiconductor device of claim 10, wherein at least a portion of an upper surface of the active pattern is in contact with the conductive pad pattern.

12. A semiconductor device comprising:
a conductive line extending in a first horizontal direction;
a first active pattern and a second active pattern on the conductive line;
a first gate electrode and a second gate electrode on the conductive line; and
a first conductive pad pattern and a second conductive pad pattern on the first and second gate electrodes, respectively,
wherein each of the first and second active patterns comprises:
a lower active portion electrically connected to an upper surface of the conductive line;
a first vertical active portion extending from the lower active portion; and
a second vertical active portion extending from the lower active portion,
wherein the first gate electrode is between the first vertical active portion of the first active pattern and the second vertical active portion of the first active pattern, and is on the lower active portion of the first active pattern,
wherein the second gate electrode is between the first vertical active portion of the second active pattern and the second vertical active portion of the second active pattern, and is on the lower active portion of the first second active pattern,
wherein the first conductive pad pattern is electrically connected to the first vertical active portion of the first active pattern and the second vertical active portion of the first active pattern, and
wherein the second conductive pad pattern is electrically connected to the first vertical active portion of the second active pattern and the second vertical active portion of the second active pattern.

13. The semiconductor device of claim 12, wherein respective widths of the first and second conductive pad patterns in the first horizontal direction are greater than respective widths of the first and second active patterns in the first horizontal direction.

14. The semiconductor device of claim 12, wherein the first conductive pad pattern comprises:
an upper pad portion on the first active pattern;
a first lower pad portion extending from the upper pad portion and contacting a side surface of the first vertical active portion of the first active pattern; and
a second lower pad portion extending from the upper pad portion and contacting a side surface of the second vertical active portion of the first active pattern.

15. The semiconductor device of claim 14, wherein the first lower pad portion is in contact with at least a portion of an upper surface of the first vertical active portion.

16. The semiconductor device of claim 12, wherein the first conductive pad pattern comprises:
an upper pad portion on the first active pattern; and
a lower pad portion extending from a central portion of the upper pad portion and contacting a side surface of the first vertical active portion of the first active pattern and a side surface of the second vertical active portion of the first active pattern.

17. The semiconductor device of claim 16, wherein the lower pad portion is in contact with at least a portion of an upper surface of the first vertical active portion.

18. A semiconductor device comprising:
a conductive line extending in a first horizontal direction;
a cell transistor on the conductive line; and
a conductive pad pattern on the cell transistor,
wherein the cell transistor comprises:
an active pattern including a first vertical channel portion and a second vertical channel portion spaced apart from each other in the first horizontal direction;
a single gate electrode between the first and second vertical channel portions; and
a gate dielectric layer between the single gate electrode and the active pattern, and
wherein the conductive pad pattern contacts upper regions of the first and second vertical channel portions.

19. The semiconductor device of claim 18, wherein the first vertical channel portion has a first side surface facing the second vertical channel portion and a second side surface opposing the first side surface,
wherein the second vertical channel portion has a third side surface facing the first vertical channel portion and a fourth side surface opposing the third side surface, and
wherein the conductive pad pattern comprises:
an upper pad portion;
a first lower pad portion extending from the upper pad portion and contacting the second side surface of the first vertical channel portion; and
a second lower pad portion extending from the upper pad portion and contacting the fourth side surface of the second vertical channel portion.

20. The semiconductor device of claim 18, wherein the first vertical channel portion has a first side surface facing the second vertical channel portion and a second side surface opposing the first side surface,
wherein the second vertical channel portion has a third side surface facing the first vertical channel portion and a fourth side surface opposing the third side surface, and
wherein the conductive pad pattern comprises:
an upper pad portion; and
a lower pad portion extending from a central area of the upper pad portion and contacting the first side surface of the first vertical channel portion and the third side surface of the second vertical channel portion.
